(19) United States
(12) Patent Application Publication
(10) Pub. No.: US 2014/0183726 A1
(43) Pub. Date: Jul. 3, 2014

(54) PACKAGE SUBSTRATE, METHOD FOR MANUFACTURING THE SAME, AND PACKAGE ON PACKAGE SUBSTRATE

(71) Applicant: SAMSUNG ELECTRO-MECHANICS CO., LTD., Suwon (KR)

(72) Inventors: Chang Bo LEE, Suwon (KR); Cheol ho CHOI, Hwasung (KR); Chang Sup RYU, Suwon (KR)

(73) Assignee: SAMSUNG ELECTRO-MECHANICS CO., LTD., Suwon (KR)

(21) Appl. No.: 14/073,309

(22) Filed: Nov. 6, 2013

(30) Foreign Application Priority Data
Dec. 28, 2012 (KR) 10-2012-0157162

(51) Int. Cl. H01L 23/498; H01L 21/768

(52) U.S. Cl. CPC H01L 23/49811; H01L 21/76885
USPC 257/737; 438/613

(57) ABSTRACT

The present invention relates to a package substrate, a method for manufacturing the same, and a package on package substrate. In accordance with an embodiment of the present invention, a package substrate including: an inner insulating layer; a circuit pattern layer formed on the inner insulating layer; an outer insulating layer formed on the inner insulating layer to protect the circuit pattern layer and expose portions of external and internal patterns of the circuit pattern layer; a mixed pattern layer consisting of post bumps and outermost layer patterns formed on the portions of the internal and external patterns exposed by the outer insulating layer; and a resist layer formed on the outer insulating layer to protect the outermost layer patterns of the mixed pattern layer and expose the outermost layer patterns by an open region.

### CROSS-REFERENCE TO RELATED APPLICATIONS

Claim and incorporate by reference domestic priority application and foreign priority application as follows:

“CROSS REFERENCE TO RELATED APPLICATION

This application claims the benefit under 35 U.S.C. Section 119 of Korean Patent Application Serial No. 10-2012-0157162, entitled filed Dec. 28, 2012, which is hereby incorporated by reference in its entirety into this application.”

### BACKGROUND OF THE INVENTION

1. Field of the Invention

The present invention relates to a package substrate, a method for manufacturing the same, and a package on package substrate.

2. Description of the Related Art

In manufacture of printed circuit boards (PCB), since a Cu post is a kind of bump and characterized by robustness compared to a conventional Sn—Ag—Pb base bump that is easily thermally deformed, it is known to be advantageous in implementing a fine pitch. However, it is difficult to mass-produce the Cu post due to many problems in a manufacturing method in implementing the Cu post. It is one of typical examples that adhesion of chemical copper doesn't meet the standards when depositing the chemical copper on solder resist (SR). In order to overcome this problem, chemical Ni/Cu etc. is used as the chemical copper or a plasma treatment is performed on the SR surface, but since a process of removing Ni is needed or there may be a problem with packaging due to changes in characteristics of the SR surface, its range of use is very limited.

Since the Cu post is advantageous in implementing a fine pitch, there are many package substrate products in which the Cu post is formed in a mounting portion of a chip device. For example, in manufacture of package on package (POP) substrates, a post of a so-called POP region in the outer portion is formed higher than a post of a so-called C4 region in the center portion.

A method for manufacturing a conventional package substrate having this Cu post will be described with reference to FIGS. 6a to 6f. First, a solder resist layer 60′ is applied on a circuit pattern layer 20 formed on an inner insulating layer 10 (refer to FIG. 6a). External and internal patterns 21 and 23 of the circuit pattern layer, where Cu posts 51 and 53 are to be mounted, are opened (refer to FIG. 6b). At this time, referring to FIGS. 6c to 6e, first, the C4 region post 53 having a low height is formed in an inner C4 pattern region by forming a pattern in a dry film resist 40. After that, the POP post 51 having a high height is formed by applying a dry film resist 140 again and forming an outer POP region pattern. After that, a conductive layer 70 is formed on the surface of the Cu posts 51 and 53.

In general, the Cu posts 51 and 53 are formed by plating. In order to form the post by plating, it is common that the Cu post is formed by applying a seed layer 60s on a solder resist 60 as a pre-process and performing plating on the seed layer.

At this time, there is a problem with adhesion of chemical copper when depositing the chemical copper on the solder resist layer. That is, there is a problem with adhesion in the plating process when forming the post on the solder resist. In order to overcome this problem, Ni/Cu is used as the chemical copper or a plasma treatment is performed on the surface of the solder resist, but since a process of removing Ni is needed when using Ni/Cu as the chemical copper and the surface characteristics of the solder resist are changed when performing a plasma treatment, there may be a problem with packaging.

### RELATED ART DOCUMENT

### Patent Document

Patent Document 1: U.S. Patent Laid-open Publication No. US 2011/0129960 (laid-open on Jun. 2, 2011)

### SUMMARY OF THE INVENTION

The present invention has been invented in order to overcome the above-described problems and it is, therefore, an object of the present invention to provide a technique that can form a post on a build-up insulating layer without performing plating on a solder resist layer when forming the post of a package substrate.

In accordance with a first embodiment of the present invention to achieve the object, there is provided a package substrate including: an inner insulating layer; a circuit pattern layer formed on the inner insulating layer; an outer insulating layer formed on the inner insulating layer to protect the circuit pattern layer and expose portions of external and internal patterns of the circuit pattern layer; a mixed pattern layer consisting of post bumps formed on the portions of the internal patterns exposed by the outer insulating layer and outermost layer patterns formed on the portions of the external patterns exposed by the outer insulating layer; and a resist layer formed on the outer insulating layer to protect the outermost layer patterns of the mixed pattern layer and expose the outermost layer patterns by an open region.

At this time, in an example, the resist layer may include a first resist region which protects the outermost layer patterns and a second resist region which covers the outer insulating layer exposed between the post bumps and is formed at a height between the post bump and the outer insulating layer.

Further, in an example, the outer insulating layer may be made of one of thermosetting resins, photocurable resins, and photocurable and thermosetting resins, and the resist layer may be made of one selected from solder resist and photocurable resins, which is different from the material of the outer insulating layer.

Further, at this time, the outer insulating layer may be made of the same material as the inner insulating layer.

In accordance with another example, the mixed pattern layer may be made of a Cu material, the post bumps may be pads to which a flip chip is to be connected, and a solder bump or a metal post, which is to be connected to an upper package substrate, may be mounted on the outermost layer patterns through the open region of the resist layer.

At this time, in an example, a plating layer may be formed on the surface of the outermost layer patterns, where the solder bump or the metal post is mounted, and on the surface of the post bumps.

Further, in an example, a seed layer may be formed between the surface of the external and internal patterns and the mixed pattern layer and between the surface of the outer insulating layer and the mixed pattern layer.

Next, in accordance with a second embodiment of the present invention to achieve the object, there is provided a package on package substrate including a flip chip, an upper package substrate, and a lower package substrate, wherein the lower package substrate includes an inner insulating layer; a circuit pattern layer formed on the inner insulating layer; an outer insulating layer formed on the inner insulating layer to protect the circuit pattern layer and expose portions of external and internal patterns of the circuit pattern layer; a mixed pattern layer consisting of post bumps formed on the portions of the internal patterns exposed by the outer insulating layer to be connected to the flip chip and outermost layer patterns formed on the portions of the external patterns exposed by the outer insulating layer; and a resist layer formed on the outer insulating layer to protect the outermost layer patterns of the mixed pattern layer and expose the outermost layer patterns by an open region, and the upper package substrate is connected to the lower package substrate by a connection member mounted on the outermost layer patterns through the open region of the resist layer.

At this time, in an example, the resist layer may include a first resist region which protects the outermost layer patterns and a second resist region which covers the outer insulating layer exposed between the post bumps and is formed at a height between the post bump and the outer insulating layer.

Further, in an example, the outer insulating layer may be made of one of thermosetting resins, photocurable resins, and photocurable and thermosetting resins, and the resist layer may be made of one selected from solder resist and photocurable resins, which is different from the material of the outer insulating layer.

Further, in an example, the mixed pattern layer may be made of a Cu material, the connection member may be a solder bump or a metal post, and a plating layer may be formed on the surface of the post bumps, which are connected to the flip chip, and on the surface of the outermost layer patterns on which the connection member is mounted.

In another example, a seed layer may be formed between the surface of the external and internal patterns and the mixed pattern layer and between the surface of the outer insulating layer and the mixed pattern layer.

Next, in accordance with a third embodiment of the present invention to achieve the object, there is provided a method for manufacturing a package substrate, including the steps of: laminating an outer insulating layer for protecting a circuit pattern layer on an inner insulating layer having the circuit pattern layer thereon; processing the outer insulating layer to expose portions of external and internal patterns of the circuit pattern layer; forming post bumps on the portions of the internal patterns exposed by processing of the outer insulating layer and forming outermost layer patterns on the portions of the external patterns exposed by processing of the outer insulating layer at the same time; and forming a resist layer on the outer insulating layer to protect the outermost layer patterns and expose portions of the outermost layer patterns by an open region.

At this time, in an example, in the step of forming the resist layer, the resist layer including a first resist region which protects the outermost layer patterns and exposes the portions of the outermost layer patterns and a second resist region which covers the outer insulating layer exposed between the post bumps and is formed at a height between the post bump and the outer insulating layer is formed.

Further, at this time, in the step of forming the resist layer, the first resist region may expose the portions of the outermost layer patterns and the second resist region may be formed lower than the height of the post bump by changing the intensity of development on the resist applied on the outer insulating layer.

Further, in an example, the outer insulating layer may be made of one of thermosetting resins, photocurable resins, and photocurable and thermosetting resins, and the resist layer may be made of one selected from solder resist and photocurable resins, which is different from the material of the outer insulating layer.

Further, in an example, the post bumps and the outermost layer patterns may be made of a Cu material. Further, the method for manufacturing a package substrate may further include the step of mounting a metal post or a solder bump on the outermost layer patterns exposed through the open region of the resist layer.

In another example, the method for manufacturing a package substrate may further include the steps of forming a seed layer by electroless plating on the surface of the external and internal patterns, which is exposed by processing of the outer insulating layer, and on the surface of the outer insulating layer before forming the post bumps and the outermost layer patterns; and performing flash etching to remove the seed layer between the post bumps and the outermost layer patterns.

Further, at this time, the step of forming the post bumps and the outermost layer patterns may include the steps of laminating a dry film resist on the seed layer and forming a resist pattern; and performing electroplating for forming the post bumps and the outermost layer patterns along the resist pattern and removing the dry film resist.

Further, in an example, in the step of forming the seed layer, the seed layer may be formed by electroless copper plating after performing a desmear treatment on the surface of the external and internal patterns, which is exposed by processing of the outer insulating layer, and on the surface of the outer insulating layer before performing the electroless plating.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view schematically showing a package substrate in accordance with an embodiment of the present invention;

FIG. 2 is a view schematically showing a package substrate in accordance with another embodiment of the present invention;

FIG. 3 is a view schematically showing a package on package substrate in accordance with an embodiment of the present invention;

FIGS. 4a to 4e are views schematically showing each step of a method for manufacturing a package substrate in accordance with another embodiment of the present invention;

FIGS. 5a and 5b are views schematically showing each step of the method for manufacturing a package substrate after the step according to FIG. 4d; and

FIGS. 6a to 6f are views schematically showing each step of a conventional method for manufacturing a package substrate.

### DETAILED DESCRIPTION OF THE PREFERABLE EMBODIMENTS

Embodiments of the present invention to achieve the above-described objects will be described with reference to the accompanying drawings. In this description, the same elements are represented by the same reference numerals, and additional description which is repeated or limits interpretation of the meaning of the invention may be omitted.

In this specification, when an element is referred to as being “connected or coupled to” or “disposed in” another element, it can be “directly” connected or coupled to or “directly” disposed in the other element or connected or coupled to or disposed in the other element with another element interposed therebetween, unless it is referred to as being “directly coupled or connected to” or “directly disposed in” the other element.

Although the singular form is used in this specification, it should be noted that the singular form can be used as the concept representing the plural form unless being contradictory to the concept of the invention or clearly interpreted otherwise. It should be understood that the terms such as “having”, “including”, and “comprising” used herein do not preclude existence or addition of one or more other elements or combination thereof.

The drawings referenced in this specification are provided as examples to describe the embodiments of the present invention, and the shape, the size, and the thickness may be exaggerated in the drawings for effective description of technical features.

Package Substrate

First, a package substrate in accordance with a first embodiment of the present invention will be specifically described with reference to the drawings. At this time, the reference numeral that is not mentioned in the reference drawing may be the reference numeral that represents the same element in another drawing.

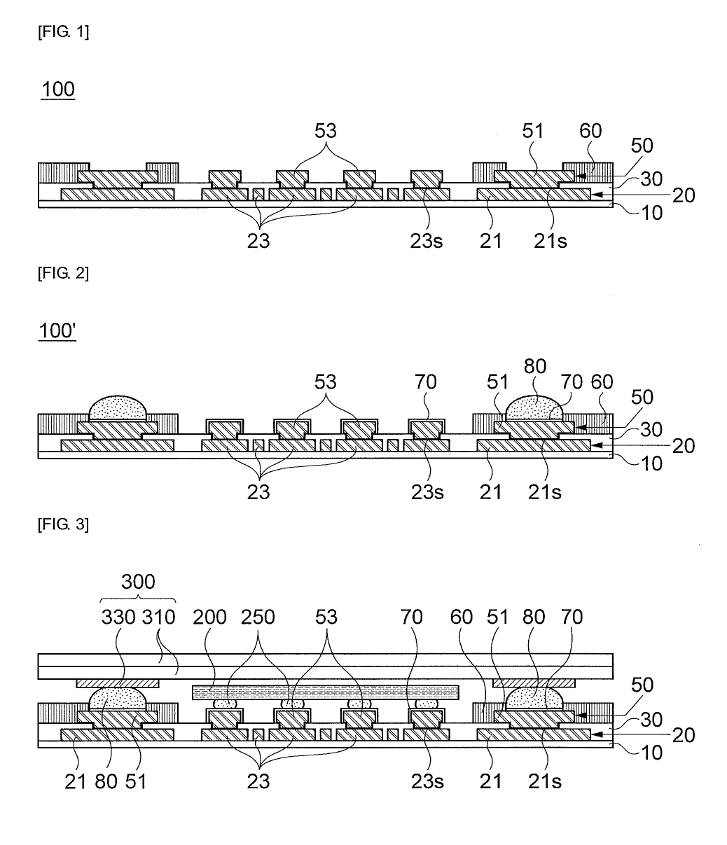

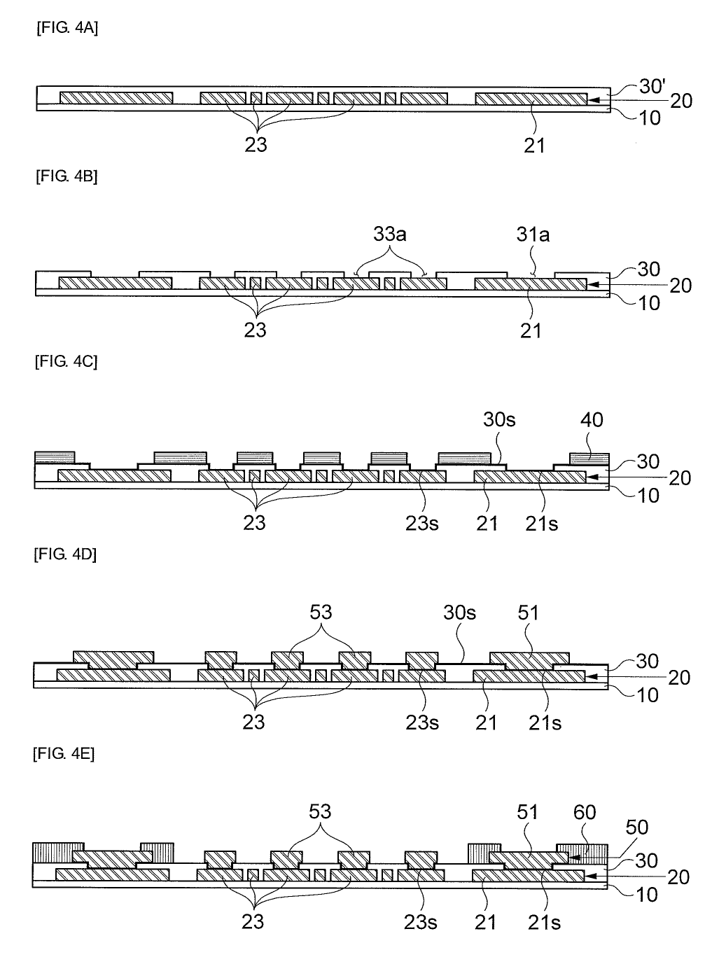

FIG. 1 is a view schematically showing a package substrate in accordance with an embodiment of the present invention, and FIG. 2 is a view schematically showing a package substrate in accordance with another embodiment of the present invention. Further, FIGS. 5a and 5b, which are views schematically showing each step of a method for manufacturing a package substrate after the step according to FIG. 4d, schematically show a package substrate in accordance with an example.

Referring to FIGS. 1, 2, 5a and/or 5b, a package substrate 100 and 100′ in accordance with an example may include an inner insulating layer 10, a circuit pattern layer 20, an outer insulating layer 30, a mixed pattern layer 50, and a resist layer 60.

The inner insulating layer 10 is an insulating layer which forms a build-up layer in a typical laminated substrate. Therefore, the inner insulating layer 10 may be made of a typical insulating substrate material. For example, thermosetting resins such as prepreg (PPG) and Ajinomoto build-up film (ABF), photocurable resins, and photocurable and thermosetting resins may be used. Although not shown, vias may be formed in the inner insulating layer 10 to conduct with or pass through the inside of the inner insulating layer 10 in addition to the circuit pattern layer 20 formed on the inner insulating layer 10.

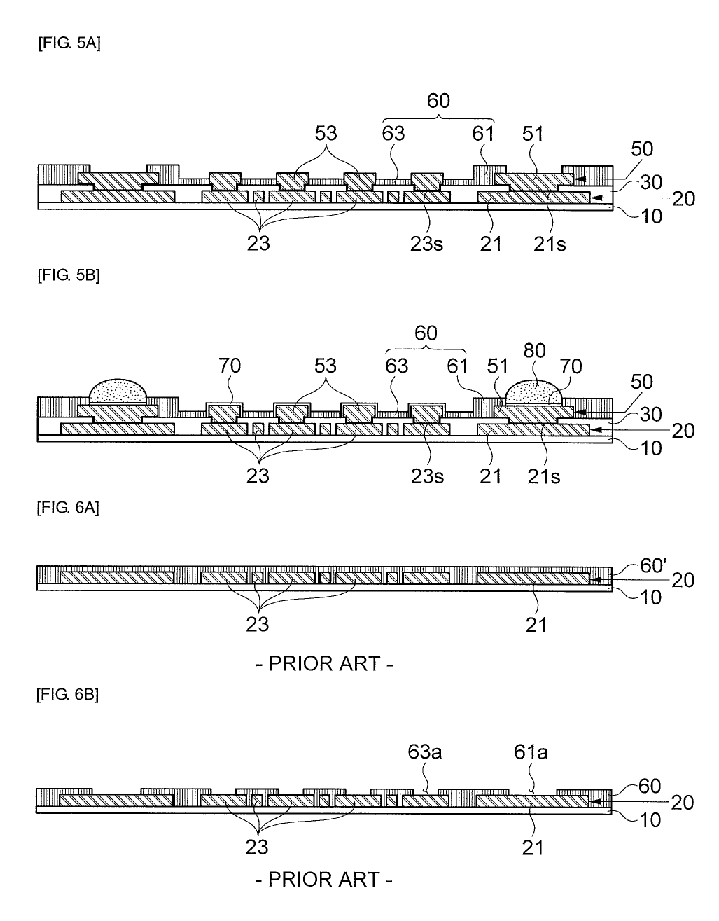

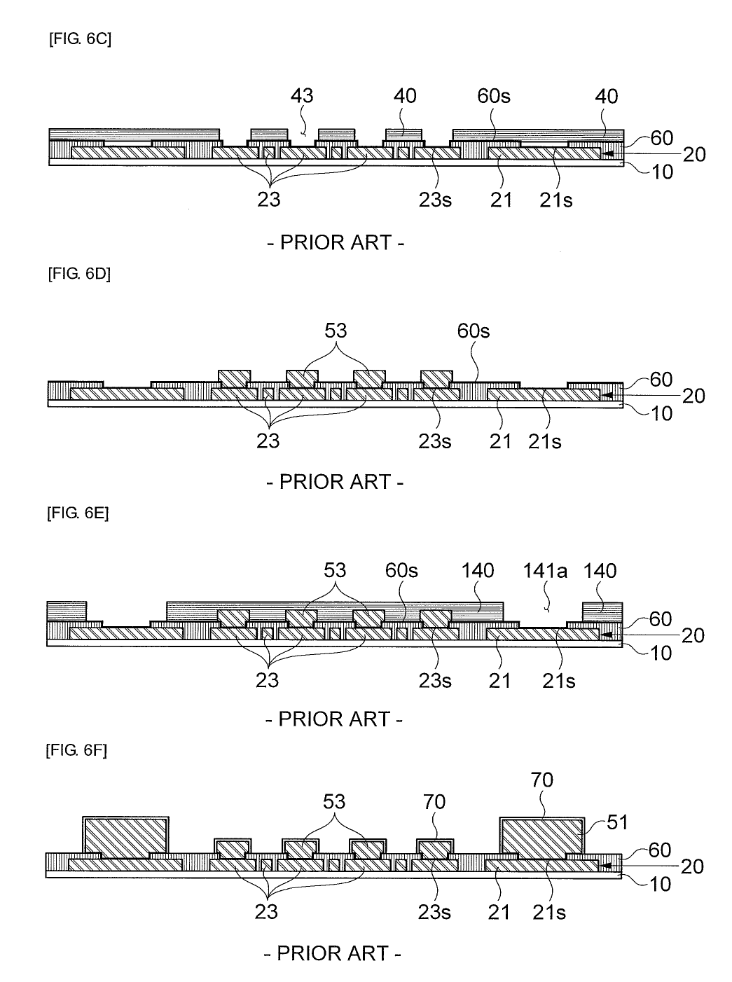

The circuit pattern layer 20 is formed on the inner insulating layer 10. In case of the typical package substrate 100 and 100′, the circuit pattern layer 20 formed on the inner insulating layer 10 is protected by a solder resist layer (refer to 60 of FIGS. 6b to 6f), but in the present invention, the circuit pattern layer 20 is protected by the outer insulating layer 30.

Next, referring to FIGS. 1, 2, 5a and/or 5b, the outer insulating layer 30 is formed on the inner insulating layer 10 to protect the circuit pattern layer 20. That is, the outer insulating layer 30 is laminated on the inner insulating layer 10 on which the circuit pattern layer 20 is formed. At this time, the outer insulating layer 30 is processed to be open so that the circuit pattern layer 20 can be connected to the outside. Accordingly, the outer insulating layer 30 exposes portions of external and internal patterns 21 and 23 of the circuit pattern layer 20 to the outside thereof. At this time, the outer insulating layer 30 may be perforated by drilling, laser processing, or photolithography processing. For example, when the outer insulating layer 30 is made of a thermosetting resin material, it may be opened by laser drilling etc., and when the outer insulating layer 30 is made of a photocurable resin material, it may be opened by a photolithography method or laser drilling. For example, the outer insulating layer 30 may be perforated in the same manner as a via forming method.

For example, in an example, the outer insulating layer 30 may be made of one of thermosetting resins, photocurable resins, and photocurable and thermosetting resins. For example, the thermosetting resins may be PPG, ABF, etc. For example, the outer insulating layer 30 may be made of the same material as the inner insulating layer 10.

For example, it is possible to avoid deterioration of adhesion when forming a chemical copper seed layer 60s on the conventional solder resist (refer to 60 of FIGS. 6c to 6f) by forming post bumps 53, for example, Cu posts on the outer insulating layer 30.

Next, referring to FIGS. 1, 2, 5a and/or 5b, the mixed pattern layer 50 may consist of the post bumps 53 and outermost layer patterns 51. At this time, the post bumps 53 may be formed in an inner region of the package substrate 100 and 100′, and the outermost layer patterns 51 may be formed in an outer region of the package substrate 100 and 100′. The post bumps 53 may be formed on the portions of the internal patterns 23 exposed by the outer insulating layer 30. At this time, the internal patterns 23 mean the patterns that are formed in an inner section of the package substrate 100 and 100′ among the patterns of the circuit pattern layer 20. The portions of the internal patterns 23 may be electrically connected to an external device, for example, a flip chip (refer to 200 of FIG. 3) through the post bumps 53. Further, the outermost layer patterns 51 may be formed on the portions of the external patterns 21 exposed by the outer insulating layer 30. At this time, the portions of the external patterns 21 may be electrically connected to an upper package substrate (refer to 300 of FIG. 3) through the outermost layer patterns 51 when configuring an external package, for example, a package on package (POP) substrate.

Accordingly, the post bumps 53 may form a so-called controlled collapse chip connection (C4) pattern region connected, for example, to the flip chip 200, and the outermost layer patterns 51 may form a so-called POP pattern region connected, for example, to the upper package substrate 300 of the POP substrate. For example, the post bumps 53 may be pads to which the flip chip 200 is to be connected. The flip chip 200 may be mounted on the post bumps 53 when configuring the POP substrate.

The post bumps 53 and the outermost layer patterns 51 may be made of a conductive metal material, for example, a Cu material. For example, the post bumps 53 and the outermost layer patterns 51 may be formed by plating copper (Cu) that is typically used. At this time, electroplating, electroless plating, sputtering, or deposition plating may be used.

Continuously, referring to FIGS. 1, 2, 5a and/or 5b, the resist layer 60 of the package substrate 100 and 100′ is formed on the outer insulating layer 30. In FIGS. 1, 2, 5a and/or 5b, the resist layer 60 is represented by the same reference numeral as FIGS. 6b to 6f of the prior art. That is, the resist layer 60 may be the solder resist layer 60. Further, the resist layer 60 may be made of an insulating material different from the solder resist layer in FIGS. 6b to 6f of the prior art in spite of the same reference numeral.

At this time, the resist layer 60 protects the outermost layer patterns 51 of the mixed pattern layer 50 on the outer insulating layer 30. That is, the resist layer 60 performs the same role as the solder resist. For example, as shown in FIGS. 1 and 2, the resist layer 60 may be formed to protect the outermost layer patterns 51 except the post bumps 53 of the mixed pattern layer 50. At this time, the resist layer 60 exposes the outermost layer patterns 51 by an open region.

Otherwise, referring to FIGS. 5a and 5b, in an example, the resist layer 60 may include a first resist region 61 and a second resist region 63. At this time, the first resist region 61 protects the outermost layer patterns 51 and exposes some surfaces of the outermost layer patterns 51 by the open region. Further, the second resist region 63 covers the outer insulating layer 30 exposed between the post bumps 53. Of course, the second resist region 63 covers the outer insulating layer 30 exposed between the first resist region 61 and the post bumps 53. At this time, the second resist region 63 may be formed at a height between the post bump 53 and the outer insulating layer 30. For example, it is possible to form the open region of the first resist region 61 and the height of the second resist region 63 by adjusting the intensity of development on the resist material applied on the outer insulating layer 30.

For example, in an example, the resist layer 60 may be made of one selected from solder resist and photocurable resins, which is different from the material of the outer insulating layer 30. That is, the resist layer 60 may be made of a different material from the outer insulating layer 30. When the resist layer 60 is made of solder resist, it can protect the outermost layer patterns 51 from the outside and block connection with the outermost layer patterns 51 due to unexpected soldering etc. For example, when a solder bump 80 as a connection member is formed on the outermost layer patterns 51 through the open region of the resist layer 60, solder resist may be used as the resist layer 60. Further, when the resist layer 60 is made of a photocurable resin, it is possible to prevent whitening due to material characteristics during desmearing and improve adhesion with chemical copper for forming a seed layer 21s, 23s, and 30s.

Further, referring to FIGS. 1, 2, 5a, and/or 5b, the resist layer 60 exposes the outermost layer patterns 51 by the open region. For example, referring to FIGS. 5a and/or 5b, the first region 61 of the resist layer 60 exposes the outermost layer patterns 51 by the open region. At this time, the connection member, for example, the solder bump 80 or a metal post, which is connected, for example, to the upper package substrate 300 when configuring, for example, the POP substrate through the open region of the resist layer 60 or the first resist region 61, may be mounted on the outermost layer patterns 51. At this time, the so-called POP pattern region in which the outermost layer patterns 51 are formed may be formed higher than the so-called C4 pattern region in which the post bumps 53 are formed. Thus, since the outermost layer patterns 51 can be connected to the upper package substrate 300 only through the solder bump 80 when configuring, for example, the POP substrate as shown in FIG. 3, it is not needed to form a separate metal post on the outermost layer patterns 51. In case of the prior art, since the so-called C4 pattern region and the so-called POP pattern region have the same height, if a common ball bump is used when a POP pitch is short, a bridging defect occurs. On the other hand, in the present embodiment, since the so-called POP pattern region has a step with the so-called C4 pattern region in which the post bumps 53 are formed by the resist layer 60 of FIGS. 1 and 2 or the first resist region 61 of FIGS. 5a and 5b and the so-called POP pattern region, which is formed to be stepped by the resist layer 60 of FIGS. 1 and 2 or the first resist region 61 of FIGS. 5a and 5b, is higher than the post bumps, for example, Cu posts, it is possible to prevent or reduce bridging defects even when using a common ball bump.

Further, referring to FIG. 2, in an example, a plating layer 70 may be formed on the surface of the outermost layer patterns 51, where the solder bumps 80 or the metal posts as the connection members are mounted, and on the surface of the post bumps 53. At this time, the plating layer 70 may be made of a metal material such as tin (Sn), gold (Au), silver (Ag), titanium (Ti), or nickel (Ni).

Further, referring to FIGS. 1, 2, 5a and/or 5b, in an example, the seed layer 21s, 23s, and 30s may be formed between the surface of the external and internal patterns 21 and 23 of the circuit pattern layer 20 and the mixed pattern layer 50 and between the surface of the outer insulating layer 30 and the mixed pattern layer 50. For example, before plating the mixed pattern layer 50, the conductive seed layer 21s, 23s, and 30s may be formed on the surface of the external and internal patterns 21 and 23 of the circuit pattern layer 20, which corresponds to a bonding portion of the mixed pattern layer 50, and on the surface of the outer insulating layer 30. At this time, the chemical copper process for forming the seed layer 21s, 23s, and 30s is applied only to the outer insulating layer 30 and is not applied to the resist layer 60.

For example, the seed layer 21s, 23s, and 30s may be formed of copper (Cu) by electroless plating. In the prior art, a seed layer (refer to 60s of FIGS. 6c to 6f) is formed on the solder resist layer (refer to 60 of FIGS. 6c to 6f). At this time, chemical copper, for example, an electroless copper plating layer, which forms the seed layer 60s, has low adhesion with the solder resist layer (refer to 60 of FIGS. 6c to 6f). On the other hand, in the present embodiment, since the seed layer 30s is formed on the outer insulating layer 30, it is possible to improve the adhesion than the conventional structure.

For example, it is possible to improve roughness of the outer insulating layer 30 coupled with the seed layer 30s by performing a desmear treatment on the outer insulating layer 30 and the perforated portion before forming the seed layer 21s, 23s, and 30s. Accordingly, it is possible to improve the adhesion between the seed layer 30s and the outer insulating layer 30.

Method for Manufacturing Package Substrate

Next, a method for manufacturing a package substrate in accordance with a third embodiment of the present invention will be specifically described with reference to the drawings. At this time, the package substrate in accordance with the above-described first embodiment and FIGS. 1 and 2 will be referenced. Thus, repeated descriptions may be omitted.

FIGS. 4a to 4e are views schematically showing each step of a method for manufacturing a package substrate in accordance with another embodiment of the present invention.

FIGS. 5a and 5b are views schematically showing each step of the method for manufacturing a package substrate after the step according to FIG. 4d.

Referring to FIGS. 4a to 4e, a method for manufacturing a package substrate in accordance with an example may include an outer insulating layer laminating step (refer to FIG. 4a), an outer insulating layer processing step (refer to FIG. 4b), a mixed pattern layer forming step (refer to FIGS. 4c and 4d), and a resist layer forming step (refer to FIG. 4e). Further, referring to the structure of FIG. 2, the method may further include a connection member mounting step.

First, referring to FIG. 4a, in the outer insulating layer laminating step, an inner insulating layer 10 having a circuit pattern layer 20 thereon is prepared, and an outer insulating layer 30 for protecting the circuit pattern layer 20 is laminated on the inner insulating layer 10. The circuit pattern layer 20 formed on the inner insulating layer 10 may be divided into internal patterns 23 and external patterns 21 according to the forming positions of post bumps 53 and outermost layer layers 51 which will be formed later. The internal patterns 23 of the circuit pattern layer 20 mean the patterns formed in an inner section of a package substrate 100 and 100′ among the patterns of the circuit pattern layer 20, and the external patterns 21 mean the patterns formed in an outer section of the package substrate 100 and 100′. Portions of the internal patterns 23 of the circuit pattern layer 20 may be electrically connected to an external device, for example, a flip chip 200 through the post bumps 53. Further, portions of the external patterns 21 of the circuit pattern layer 20 may be electrically connected to an upper package substrate 300 through the outermost layer patterns 51 when configuring an external package, for example, a POP substrate.

In FIG. 4a, the reference numeral 30′ represents the state before the material of the inner insulating layer 10 is laminated and cured, and the reference numeral 30′ becomes equal to the reference numeral 30 when the material of the inner insulating layer 10 is cured. Since the inner insulating layer 10 is an insulating layer that forms a build-up layer in a typical laminated substrate, a typical insulating substrate material can be used. The outer insulating layer also may use a typical build-up insulating material.

For example, in an example, the outer insulating layer 30 may be made of one of thermosetting resins, photocurable resins, and photocurable and thermosetting resins. For example, the thermosetting resins may be PPG, ABF, etc.

Further, in an example, the outer insulating layer 30 may be made of the same material as the inner insulating layer 10.

Next, referring to FIG. 4b, in the outer insulating layer processing step, the outer insulating layer 30 is processed to expose the portions of the external and internal patterns 21 and 23 of the circuit pattern layer 20. Since the outer insulating layer 30 may be made of a typical substrate insulating material, it is processed equally or similarly to via processing that is a method of processing an insulating layer of a substrate. For example, when the outer insulating layer 30 is made of a thermosetting resin material, it may be processed to expose the portions of the external and internal patterns 21 and 23 of the circuit pattern layer 20 by laser processing such as CO2 laser or Yag laser. Further, when the outer insulating layer 30 is made of a photocurable resin material, it may be processed to expose the portions of the external and internal patterns 21 and 23 by a photolithography method or laser processing such as CO2 laser or Yag laser.

In FIG. 4b, the reference numeral 31a represents a region which exposes the portions of the external patterns 21 of the circuit pattern layer 20, that is, a region in which the outermost layer patterns 51 are mounted, and the reference numeral 33a represents a region which exposes the portions of the internal patterns 23 of the circuit pattern layer 20, that is, a region in which the post bumps 53 are mounted.

At this time, a desmear treatment may be performed to remove a smear generated by processing of the outer insulating layer. It is possible to improve surface roughness of the outer insulating layer 30 by performing a desmear treatment on the surface of the outer insulating layer.

In an example, referring to FIGS. 4b and 4c, a seed layer forming step may be further included between the outer insulating layer processing step and the mixed pattern layer forming step. A seed layer 21s, 23s, and 30s is a layer which is pre-formed for growth of the mixed pattern layer 50 when plating the mixed pattern layer 50. At this time, in the seed layer forming step, before forming the post bumps 53 and the outermost layer patterns 51, the seed layer 21s, 23s, and 30s may be formed on the surface of the external and internal patterns 21 and 23, which is exposed by processing of the outer insulating layer 30, and on the surface of the outer insulating layer 30. Referring to FIGS. 6c and 5e, in the prior art, since a seed layer (60s of FIGS. 6c and 5e) is formed on a solder resist layer (60 of FIGS. 6c and 5e), the seed layer (60s of FIGS. 6c and 5e) has low adhesion, but referring to FIGS. 4c and 4d, in the present embodiment, since the seed layer 30s is formed on the outer insulating layer 30, the adhesion of chemical copper by electroless plating is increased. For example, the seed layer 21s, 23s, and 30s may be formed by electroless copper plating. After forming a mixed pattern layer 50, the seed layer remaining in the region without the mixed pattern layer 50 may be removed, for example, by flash etching.

Further, although not shown directly, in an example, in the seed layer forming step, the seed layer 21s, 23s, and 30s may be formed by electroless copper plating after performing a desmear treatment on the surface of the external and internal patterns 21 and 23, which is exposed by processing of the outer insulating layer 30, and on the surface of the outer insulating layer 30 before performing electroless plating. For example, it is possible to improve the roughness of the outer insulating layer 30 coupled with the seed layer 30s by performing a desmear treatment. Accordingly, it is possible to increase the adhesion between the seed layer 30s and the outer insulating layer 30.

Next, the mixed pattern layer forming step will be described with reference to FIGS. 4c and 4d. At this time, the mixed pattern layer 50 consists of the post bumps 53 and the outermost layer patterns 51. In the mixed pattern layer forming step, the post bumps 53 and the outermost layer patterns 51 are formed at the same time. At this time, the post bumps 53 are formed on the portions of the internal patterns 23 of the circuit pattern layer 20 exposed by processing of the outer insulating layer 30. At the same time, the outermost layer patterns 51 are formed on the portions of the external patterns 53 of the circuit pattern layer 50 exposed by processing of the outer insulating layer 30. At this time, the post bumps 53 may be electrically connected to an external device, for example, the flip chip 200 after completion of the package substrate. Further, the outermost layer patterns 51 may be electrically connected to the upper package substrate 300 after the completion of the package substrate, for example, when configuring the POP substrate. That is, the post bumps 53 may form a so-called C4 pattern region connected, for example, to the flip chip 200, and the outermost pattern layers 51 may form a so-called POP pattern region connected to the upper package substrate 300 of the POP substrate. For example, the post bumps 53 may be pads to which the flip chip 200 is to be connected. The flip chip 200 may be mounted on the post bumps 53 after manufacturing the package substrate 100 and 100′, for example, when configuring the POP substrate.

The post bumps 53 and the outermost layer patterns 51 may be made of a conductive metal material, for example, a Cu material. For example, the post bumps 53 and the outermost layer patterns 51 may be formed by plating copper (Cu) that is typically used. At this time, electroplating, electroless plating, sputtering, deposition plating, etc, may be used. For example, when forming the post bumps 53 and the outermost layer patterns 51 by plating, the seed layer 21s, 23s, and 30s may be formed in advance, and when the post bumps 53 and the outermost layer patterns 51 are formed on the seed layer 21s, 23s, and 30s, they may be plated, for example, by electroplating.

The mixed pattern layer forming step will be specifically described with reference to FIGS. 4c and 4d. In an example, the mixed pattern layer forming step may include a dry film resist laminating step (refer to FIG. 4c) and an electroplating and resist removing step (refer to FIG. 4d). At this time, the above-described seed layer forming step may be performed in advance before the mixed pattern layer forming step.

Referring to FIG. 4c, in the dry film resist laminating step, a dry film resist (DFR) 40 is laminated on the seed layer 21s, 23s, and 30s, and a resist pattern is formed. The resist pattern is a pattern for forming the post bumps 53 and the outermost layer patterns 51 later by plating.

Next, referring to FIG. 4d, in the electroplating and resist removing step, electroplating is performed to form the post bumps 53 and the outermost layer patterns 51 along the resist pattern. Further, in the electroplating and resist removing step, the DFR 40 is removed after electroplating. When the DFR 40 is removed, the post bumps 53 and the outermost layer patterns 51 are left. For example, at this time, a lapping process may be performed to finish the surface of the post bumps 53 and the outermost layer patterns 51 before removing the DFR 40.

Further, comparing FIGS. 4d and 4e, a remaining seed layer removing step may be further included after removing the DFR 40. That is, before forming the resist layer 60 after removing the DFR 40, the remaining seed layer between the post bumps 53 and the outermost layer patterns 51 may be removed by flash etching.

Next, the resist layer forming step will be described with reference to FIGS. 4e and/or 5a. FIGS. 4e and 5a show the resist layer forming step, respectively, and may be selective according to the embodiments. Referring to FIGS. 4e and 5a, in the resist layer forming step, the resist layer 60 is formed on the outer insulating layer 30. At this time, the resist layer 60 protects the outermost layer patterns 51 and exposes the portions of the outermost layer patterns 51 by the open region. For example, the resist layer 60 may perform the same role as the conventional solder resist layer.

For example, in an example, as shown in FIG. 4e, the resist layer 60 may be formed to protect the outermost layer patterns 51 except the post bumps 53 of the mixed pattern layer 50. At this time, the resist layer 60 exposes the outermost layer patterns 51 by the open region.

Otherwise, in another example, referring to FIG. 5a, the resist layer 60 including a first resist region 61 and a second resist region 63 may be formed on the outer insulating layer 30. At this time, the first resist region 61 protects the outermost layer patterns 51 and exposes some surfaces of the outermost layer patterns 51 by the open region.

Further, the second resist region 63 covers the outer insulating layer 30 exposed between the post bumps 53. At this time, the second resist region 63 may be formed at a height between the post bump 53 and the outer insulating layer 30.

For example, in an example, it is possible to form the open region of the first resist region 61 and the height of the second resist region 63 by adjusting the intensity of development on the resist material applied on the outer insulating layer 30. That is, the first resist region 61 may expose the portions of the outermost layer patterns 51, and the second resist region 61 may be formed lower than the height of the post bump 53.

Referring to FIGS. 4e and 5a, according to the formation of the resist layer, the so-called POP pattern region in which the outermost layer patterns 51 are formed may be formed higher than the so-called C4 pattern region in which the solder bumps 53 are formed. Since the so-called POP pattern region in which the outermost layer patterns 51 are formed is formed higher than the so-called C4 pattern region in which the post bumps 53 are formed, it is not needed to form a separate post on the outermost layer patterns 51. Referring to FIGS. 2 or 5b and 3, it is shown that a solder bump 80, not a metal post, is formed on the outermost layer patterns 51 exposed by the open region of the resist layer 60 of FIG. 2 or the first resist region 61 of FIG. 5b. Although not shown, according to the embodiments, it is possible to add a metal post on the outermost layer patterns.

For example, at this time, referring to FIGS. 4e and/or 5a, the resist layer 60 may be made of one selected from solder resist and photocurable resins, which is different from the material of the outer insulating layer 30. For example, when the solder bump 80 as a connection member is formed on the outermost layer patterns 51 through the open region of the resist layer 60, the resist layer 60 may be made of solder resist and not limited thereto. Further, when the resist layer 60 is made of a photocurable resin, it is possible to prevent whitening due to material characteristics during desmearing and improve adhesion with chemical copper for forming a seed layer.

Further, another example will be described with reference to FIGS. 2 and 5b. At this time, the method for manufacturing a package substrate may further include a connection member mounting step. For example, the metal post or the solder bump 80 as the connection member may be mounted on the outermost layer patterns 51 exposed through the open region of the resist layer 60 of FIG. 2 or the first resist region 61 of FIG. 5b. FIGS. 2 and 5b show that the solder bump 80 is mounted on the outermost layer patterns 51.

Package on Package Substrate

Next, a package on package substrate in accordance with a second embodiment of the present invention will be specifically described with reference to the drawings. At this time, the package substrate in accordance with the above-described first embodiment and FIGS. 1, 2, 5a, and 5b will be referenced. Thus, repeated descriptions may be omitted.

FIG. 3 is a view schematically showing a package on package substrate in accordance with an embodiment of the present invention.

Referring to FIG. 3, a package on package (POP) substrate in accordance with an example may include a flip chip 200, an upper package substrate 300, and a lower package substrate (refer to 100 and 100′ of FIGS. 1 and 2). The flip chip 200 may be mounted on the lower package substrate 100 and 100′, and an outer region of the lower package substrate 100 and 100′ may be connected to the upper package substrate 300 through a connection member. In FIG. 3, the reference numeral 250 represents a solder ball formed on a bottom of the flip chip 200 to be attached to post bumps 53 of the lower package substrate 100 and 100′. In FIG. 3, the reference numeral 310 represents a substrate laminate of the upper package substrate 300, and the reference numeral 330 represents a connection member, for example, a bump pad connected to a solder bump 80.

FIGS. 1, 2, 5a, and 5b shows the lower package substrate. Descriptions of the lower package substrate 100 and 100′ will refer to the above-described first to third embodiments.

Referring to FIGS. 1, 2, 3. 5a, and 5b, the lower package substrate 100 and 100′ may include an inner insulating layer 10, a circuit pattern layer 20, an outer insulating layer 30, a mixed pattern layer 50, and a resist layer 60.

The inner insulating layer 10 is made of a typical substrate insulator, for example, one of thermosetting resins, photocurable resins, and photocurable and thermosetting resins.

The circuit pattern layer 20 is formed on the inner insulating layer 10.

Referring to FIGS. 1, 2, 3, 5a, and 5b, the outer insulating layer 30 is formed on the inner insulating layer 10 to protect the circuit pattern layer 20. Further, the outer insulating layer 30 exposes portions of external and internal patterns 21 and 23 of the circuit pattern layer 20 to mount the mixed pattern layer 50 thereon.

For example, in an example, the outer insulating layer 30 may be made of one of thermosetting resins, photocurable resins, and photocurable and thermosetting resins. For example, the thermosetting resins may be PPG, ABF, etc. For example, the outer insulating layer 30 may be made of the same material as the inner insulating layer 10.

Next, the mixed pattern layer 50 consists of the post bumps 53 and outermost layer patterns 51. The post bumps 53 are formed on the portions of the internal patterns 23 of the circuit pattern layer 20 exposed by the outer insulating layer 30. At this time, the post bumps 53 are connected to the flip chip 200. The outermost layer patterns 51 are formed on the portions of the external patterns 21 of the circuit pattern layer 20 exposed by the outer insulating layer 30.

The post bumps 53 and the outermost layer patterns 51 may be made of a conductive metal material, for example, a Cu material. For example, the post bumps 53 and the outermost layer patterns 51 may be formed by plating copper (Cu) that is typically used. At this time, electroplating, electroless plating, sputtering, deposition plating, etc. may be used.

Referring to FIGS. 2, 3, and 5b, in an example, a seed layer 21s, 23s, and 30s may be formed between the surface of the external and internal patterns 21 and 23 and the mixed pattern layer 50 and between the surface of the outer insulating layer 30 and the mixed pattern layer 50. For example, the seed layer 21s, 23s, and 30s may be formed of copper (Cu) by electroless plating.

Further, referring to FIGS. 2, 3, and 5b, in an example, a plating layer 70 may be formed on the surface of the post bumps 53 connected to the flip chip 200 and on the surface of the outermost layer patterns 51 on which the connection member is mounted. At this time, the plating layer 70 may be made of a metal material such as tin (Sn), gold (Au), silver (Ag), titanium (Ti), or nickel (Ni).

Next, referring to FIGS. 1, 2, 3, 5a, and 5b, the resist layer 60 is formed on the outer insulating layer 30 to protect the outermost layer patterns 51 except the post bumps 53 of the mixed pattern layer 50. That is, the resist layer 60 performs the same role as solder resist.

For example, as shown in FIGS. 1 and 2, the resist layer 60 may be formed to protect the outermost layer patterns 51 except the post bumps 52 of the mixed pattern layer 50. At this time, the resist layer 60 exposes the outermost layer patterns 51 by an open region.

Further, referring to FIGS. 5a and 5b, in an example, the resist layer 60 may include a first resist region 61 and a second resist region 63. At this time, the first resist region 61 protects the outermost layer patterns 51 and exposes some surfaces of the outermost layer patterns 51 by the open region. Further, the second resist region 63 covers the outer insulating layer 30 exposed between the post bumps 53. At this time, the second resist region 63 may be formed at a height between the post bump 53 and the outer insulating layer 30. For example, it is possible to form the open region of the first resist region 61 and the height of the second resist region 63 by adjusting the intensity of development on the resist material applied on the outer insulating layer 30.

At this time, referring to FIG. 3, the upper package substrate 300 is connected to the lower package substrate 100 and 100′ by the connection member mounted on the outermost layer patterns 51 through the open region of the resist layer 60.

For example, in an example, the resist layer 60 may be made of one selected from solder resist and photocurable resins, which is different from the material of the outer insulating layer 30. That is, the resist layer 60 may be made of a different material from the outer insulating layer 30.

Further, in an example, the connection member may be a solder bump or a metal post. Referring to FIGS. 2, 3, and 4e, since a so-called POP pattern region in which the outermost layer patterns 51 are formed is formed higher than a so-called C4 pattern region in which the post bumps 53 are formed, it is possible to connect the outermost layer patterns 51 to the upper package substrate 300 only through the solder bump 80 without forming a separate post on the outermost layer patterns 30. Referring to FIG. 3, a bump pad 330 of the upper package substrate 300 is in contact with the solder bump 80 formed on the outermost layer patterns 51 of the lower package substrate 100 and 100′.

According to the embodiments of the present invention, it is possible to overcome the problems in the process of plating a post by forming the post on a build-up insulating layer without performing plating on a solder resist layer when forming the post of a package substrate.

In an example, a chemical copper process for forming a seed layer is applied only to an outer build-up insulating layer and not applied to a solder resist layer. For example, it is possible to avoid the deterioration of adhesion occurring when forming a chemical copper seed layer on conventional solder resist by forming post bumps, for example, Cu posts on the outer build-up insulating layer.

Further, in accordance with an example, it is possible to obtain a package substrate structure without the need for Cu posts in a POP region by naturally forming a POP region higher than a C4 region by a resist layer.

It is apparent that various effects which have not been directly mentioned according to the various embodiments of the present invention can be derived by those skilled in the art from various constructions according to the embodiments of the present invention.

The above-described embodiments and the accompanying drawings are provided as examples to help understanding of those skilled in the art, not limiting the scope of the present invention. Further, embodiments according to various combinations of the above-described components will be apparently implemented from the foregoing specific descriptions by those skilled in the art. Therefore, the various embodiments of the present invention may be embodied in different forms in a range without departing from the essential concept of the present invention, and the scope of the present invention should be interpreted from the invention defined in the claims. It is to be understood that the present invention includes various modifications, substitutions, and equivalents by those skilled in the art.

What is claimed is:

1. A package substrate comprising:
an inner insulating layer;
a circuit pattern layer formed on the inner insulating layer;
an outer insulating layer formed on the inner insulating layer to protect the circuit pattern layer and expose portions of external and internal patterns of the circuit pattern layer;
a mixed pattern layer consisting of post bumps formed on the portions of the internal patterns exposed by the outer insulating layer and outermost layer patterns formed on the portions of the external patterns exposed by the outer insulating layer; and
a resist layer formed on the outer insulating layer to protect the outermost layer patterns of the mixed pattern layer and expose the outermost layer patterns by an open region.

2. The package substrate according to claim 1, wherein the resist layer comprises a first resist region which protects the outermost layer patterns and a second resist region which covers the outer insulating layer exposed between the post bumps and is formed at a height between the post bump and the outer insulating layer.

3. The package substrate according to claim 1, wherein the outer insulating layer is made of one of thermosetting resins, photocurable resins, and photocurable and thermosetting resins, and
the resist layer is made of one selected from solder resist and photocurable resins, which is different from the material of the outer insulating layer.

4. The package substrate according to claim 3, wherein the outer insulating layer is made of the same material as the inner insulating layer.

5. The package substrate according to claim 3, wherein the mixed pattern layer is made of a Cu material,
the post bumps are pads to which a flip chip is to be connected, and
a solder bump or a metal post, which is to be connected to an upper package substrate, is mounted on the outermost layer patterns through the open region of the resist layer.

6. The package substrate according to claim 5, wherein a plating layer is formed on the surface of the outermost layer patterns, where the solder bump or the metal post is mounted, and on the surface of the post bumps.

7. The package substrate according to claim 3, wherein a seed layer is formed between the surface of the external and internal patterns and the mixed pattern layer and between the surface of the outer insulating layer and the mixed pattern layer.

8. A package on package substrate comprising a flip chip, an upper package substrate, and a lower package substrate, wherein the lower package substrate comprises:
an inner insulating layer;
a circuit pattern layer formed on the inner insulating layer;
an outer insulating layer formed on the inner insulating layer to protect the circuit pattern layer and expose portions of external and internal patterns of the circuit pattern layer;
a mixed pattern layer consisting of post bumps formed on the portions of the internal patterns exposed by the outer insulating layer to be connected to the flip chip and outermost layer patterns formed on the portions of the external patterns exposed by the outer insulating layer; and
a resist layer formed on the outer insulating layer to protect the outermost layer patterns of the mixed pattern layer and expose the outermost layer patterns by an open region, and
the upper package substrate is connected to the lower package substrate by a connection member mounted on the outermost layer patterns through the open region of the resist layer.

9. The package on package substrate according to claim 8, wherein the resist layer comprises a first resist region which protects the outermost layer patterns and a second resist region which covers the outer insulating layer exposed between the post bumps and is formed at a height between the post bump and the outer insulating layer.

10. The package on package substrate according to claim 8, wherein the outer insulating layer is made of one of thermosetting resins, photocurable resins, and photocurable and thermosetting resins, and
the resist layer is made of one selected from solder resist and photocurable resins, which is different from the material of the outer insulating layer.

11. The package on package substrate according to claim 10, wherein the mixed pattern layer is made of a Cu material,
the connection member is a solder bump or a metal post, and
a plating layer is formed on the surface of the post bumps, which are connected to the flip chip, and on the surface of the outermost layer patterns on which the connection member is mounted.

12. The package on package substrate according to claim 10, wherein a seed layer is formed between the surface of the external and internal patterns and the mixed pattern layer and between the surface of the outer insulating layer and the mixed pattern layer.

13. A method for manufacturing a package substrate, comprising:
laminating an outer insulating layer for protecting a circuit pattern layer on an inner insulating layer having the circuit pattern layer thereon;
processing the outer insulating layer to expose portions of external and internal patterns of the circuit pattern layer;
forming post bumps on the portions of the internal patterns exposed by processing of the outer insulating layer and forming outermost layer patterns on the portions of the external patterns exposed by processing of the outer insulating layer at the same time; and
forming a resist layer on the outer insulating layer to protect the outermost layer patterns and expose portions of the outermost layer patterns by an open region.

14. The method for manufacturing a package substrate according to claim 13, wherein in forming the resist layer, the resist layer comprising a first resist region which protects the outermost layer patterns and exposes the portions of the outermost layer patterns and a second resist region which covers the outer insulating layer exposed between the post bumps and is formed at a height between the post bump and the outer insulating layer is formed.

15. The method for manufacturing a package substrate according to claim 14, wherein in forming the resist layer, the first resist region exposes the portions of the outermost layer patterns and the second resist region is formed lower than the height of the post bump by changing the intensity of development on the resist applied on the outer insulating layer.

16. The method for manufacturing a package substrate according to claim 13, wherein the outer insulating layer is made of one of thermosetting resins, photocurable resins, and photocurable and thermosetting resins, and
the resist layer is made of one selected from solder resist and photocurable resins, which is different from the material of the outer insulating layer.

17. The method for manufacturing a package substrate according to claim 16, wherein the post bumps and the outermost layer patterns are made of a Cu material, and further comprising:
mounting a metal post or a solder bump on the outermost layer patterns exposed through the open region of the resist layer.

18. The method for manufacturing a package substrate according to claim 16, further comprising:
forming a seed layer by electroless plating on the surface of the external and internal patterns, which is exposed by processing of the outer insulating layer, and on the surface of the outer insulating layer before forming the post bumps and the outermost layer patterns; and
performing flash etching to remove the seed layer between the post bumps and the outermost layer patterns.

19. The method for manufacturing a package substrate according to claim 18, wherein forming the post bumps and the outermost layer patterns comprises:
laminating a dry film resist on the seed layer and forming a resist pattern; and
performing electroplating for forming the post bumps and the outermost layer patterns along the resist pattern and removing the dry film resist.

20. The method for manufacturing a package substrate according to claim 18, wherein in forming the seed layer, the seed layer is formed by electroless copper plating after performing a desmear treatment on the surface of the external and internal patterns, which is exposed by processing of the outer insulating layer, and on the surface of the outer insulating layer before performing the electroless plating.

21. The package substrate according to claim 2, wherein the outer insulating layer is made of one of thermosetting resins, photocurable resins, and photocurable and thermosetting resins, and
the resist layer is made of one selected from solder resist and photocurable resins, which is different from the material of the outer insulating layer.

22. The package on package substrate according to claim 9, wherein the outer insulating layer is made of one of thermosetting resins, photocurable resins, and photocurable and thermosetting resins, and
the resist layer is made of one selected from solder resist and photocurable resins, which is different from the material of the outer insulating layer.

23. The method for manufacturing a package substrate according to claim 14, wherein the outer insulating layer is made of one of thermosetting resins, photocurable resins, and photocurable and thermosetting resins, and
the resist layer is made of one selected from solder resist and photocurable resins, which is different from the material of the outer insulating layer.

24. The method for manufacturing a package substrate according to claim 15, wherein the outer insulating layer is made of one of thermosetting resins, photocurable resins, and photocurable and thermosetting resins, and
the resist layer is made of one selected from solder resist and photocurable resins, which is different from the material of the outer insulating layer.
